(19) United States
(12) Patent Application Publication
(10) Pub. No.: US 2023/0246101 A1
(43) Pub. Date: Aug. 3, 2023

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventor: Toshiaki IWAMATSU, Tokyo (JP)

(73) Assignee: Mitsubishi Electric Corporation, Tokyo (JP)

(21) Appl. No.: 18/018,894

(22) PCT Filed: Sep. 30, 2020
(86) PCT No.: PCT/JP2020/037139

§ 371 Date: Jan. 31, 2023

(51) Int. Cl. H01L 29/78; H01L 29/66

(52) U.S. Cl. CPC H01L 29/7811; H01L 29/7813; H01L 29/66734; H01L 29/7397

(57) ABSTRACT

A semiconductor device according to the present disclosure includes: a diffusion protection layer in contact with a bottom surface of a gate trench provided in an active region; a termination protection layer in contact with a bottom surface of a termination trench provided in a termination region and having a width larger than the gate trench; a gate insulating film and gate wires provided in the gate trench and the termination trench; and a source electrode electrically connected to the diffusion protection layer, and the termination protection layer, wherein a termination insulating film that has a thickness equal to or larger than the thickness of the gate insulating film is formed in the termination trench, and the gate wires are formed in grooves in two or more portions with the termination insulating film interposed therebetween, surrounded by an outer peripheral wall of the termination trench and the termination insulating film.

### TECHNICAL FIELD

The present disclosure relates to a semiconductor device and a method for manufacturing a semiconductor device.

### BACKGROUND ART

In power electronics devices, insulated-gate semiconductor devices such as a metal-oxide-semiconductor field-effect transistor (MOSFET) and an insulated-gate bipolar transistor (IGBT) are widely used as switching elements for controlling power supply to a load such as a motor. Some of these insulated-gate semiconductor devices each have a trench structure in which a gate wire is buried in a semiconductor layer. An insulated-gate semiconductor device having a trench structure can increase a channel width density of an active region as compared with a planar semiconductor device in which a gate wire is formed in a surface of a semiconductor layer, thereby reducing its electric resistance per unit area in an on state of the semiconductor device.

Conventionally, in an insulated-gate semiconductor device having a trench structure, a gate wire and a gate insulating film are formed in a trench of a trench opening on an active-region side and around an upper corner of the trench in a termination region provided around an active region. When a gate voltage is applied to turn on the semiconductor device, an electric field concentrates on a bottom surface and an upper corner of the trench, which causes insulation deterioration of the gate insulating film on the bottom surface and around the corner, resulting in reduced reliability of the semiconductor device.

In order to solve this problem, there is known a method in which an electric-field relaxation region having conductivity is provided in the bottom surface of the trench, to relax an electric field applied to the gate insulating film on the bottom surface of the trench. Further, there is known a method in which a structure including a narrow and deep trench in an active region and a wide and shallow trench in a termination region is formed, and thereafter gate wires formed in the trenches in the active region and the termination region are planarized by using a chemical mechanical polishing (CMP) process or a combination of a CMP process and an etch-back process, to prevent the corner of the trench from being covered with the gate wires (see Patent Document 1, for example).

### PRIOR ART DOCUMENT

### Patent Document

Patent Document 1: Japanese Patent Application (Translation of PCT Application) Laid-Open No. 2006-520091

### SUMMARY

### Problem to be Solved by the Invention

However, according to the method in which an electric-field relaxation region is provided on a bottom surface of a trench, insulation deterioration around the upper corner of the trench cannot be reduced in some cases. In a method using a CMP process, it is necessary to considerably reduce the influence of unevenness of a film formed on a semiconductor substrate under the influence of warpage or surface unevenness of the semiconductor substrate, in-plane uniformity of the film thickness, particles, and the like, which makes it difficult to adopt the method in reality. Further, in a case where a wide trench is formed in a termination region and a gate insulating film and a gate wire are continuously deposited, an exposed area of the gate wire increases in a subsequent etch-back process, so that the gate wire is thinned or is lost as a film due to etching. Thus, stable operations of an insulated-gate semiconductor device cannot be achieved.

The present disclosure has been made to solve the above-described problems, and an object of the present disclosure is to prevent, in an insulated-gate semiconductor device having a trench structure, deterioration of a gate insulating film at a corner in an end of a trench opening in a termination region provided around an active region and reduction of reliability of the semiconductor device.

### Means to Solve the Problem

A semiconductor device according to the present disclosure includes: a semiconductor substrate; a drift layer of a first conductivity type provided on the semiconductor substrate; a base region of a second conductivity type provided on the drift layer; a plurality of source regions of the first conductivity type provided on the base region while being spaced away from each other; a gate trench passing through the source region and the base region and reaching the drift layer; a termination trench positioned in a termination region on an outer peripheral side of an active region where the gate trench is formed, the termination trench having a width larger than a width of the gate trench and passing through the base region to reach the drift layer; a diffusion protection layer of the second conductivity type formed in the drift layer while being in contact with a bottom surface of the gate trench; a termination protection layer of the second conductivity type formed in the drift layer while being in contact with a bottom surface of the termination trench; a gate insulating film formed on the diffusion protection layer, the termination protection layer, a side portion of the gate trench, and a side portion of the termination trench; a termination insulating film formed above the termination protection layer in the termination trench while being in contact with the termination protection layer, the termination insulating film having a thickness equal to or larger than a thickness of the gate insulating film; gate wires formed on the gate insulating film on an inner side of the gate trench in the gate trench, and formed in grooves in two or more portions with the termination insulating film interposed therebetween in one section, surrounded by an outer peripheral wall of the termination trench and a side portion of the termination insulating film in the termination trench, the gate wires being connected between the gate trench and the termination trench; a source electrode electrically connected to the source region and the termination protection layer; and a gate electrode provided on the gate wire in the termination trench and on the termination insulating film while being in contact with the gate wire and the termination insulating film, the gate electrode being electrically connected to the gate wire.

A method for manufacturing a semiconductor device according to the present disclosure includes: a step of forming a drift layer of a first conductivity type on a surface of a semiconductor substrate; a step of forming a base region of a second conductivity type on the drift layer; a step of forming a plurality of source regions of the first conductivity type spaced away from each other on the base region; a step of forming a gate trench passing through the source region and the base region and reaching the drift layer; a step of forming a termination trench having a width larger than a width of the gate trench and passing through the base region to reach the drift layer, in a termination region on an outer peripheral side of an active region where the gate trench is formed; a step of forming a diffusion protection layer of the second conductivity type in the drift layer such that the diffusion protection layer is in contact with a bottom surface of the gate trench; a step of forming a termination protection layer of the second conductivity type in the drift layer such that the termination protection layer is in contact with a bottom surface of the termination trench; a step of forming a termination insulating film above the termination protection layer in the termination trench such that the termination insulating film is in contact with the termination protection layer; a step of forming a gate insulating film having a thickness equal to or smaller than a thickness of the termination insulating film, on the diffusion protection layer, the termination protection layer, a side portion of the gate trench, and a side portion of the termination trench; a step of etching back a gate wire layer after depositing the gate wire layer on the termination insulating film and the gate insulating film, to form gate wires on the gate insulating film on an inner side of the gate trench in the gate trench, and in grooves in two or more portions with the termination insulating film interposed therebetween in one section, surrounded by an outer peripheral wall of the termination trench and a side portion of the termination insulating film in the termination trench such that the gate wires are connected between the gate trench and the termination trench; a step of forming a source electrode electrically connected to the source region and the termination protection layer; and a step of forming a gate electrode on the gate wire in the termination trench and on the termination insulating film such that the gate electrode is in contact with the gate wire and the termination insulating film and is electrically connected to the gate wire.

### Effects of the Invention

According to the present disclosure, the termination insulating film having a thickness equal to or larger than the thickness of the gate insulating film is formed in the termination trench, and the gate wires are formed in two or more positions with the termination insulating film interposed therebetween in a section of the termination trench. Hence, it is possible to prevent deterioration of the gate insulating film at the corner portion in the end of the trench opening in the termination region and reduction of reliability of the semiconductor device.

### BRIEF DESCRIPTION OF DRAWINGS

FIG. 1 is a schematic plan view of a semiconductor device according to a first embodiment.

FIG. 2 is an enlarged view of a schematic plan of a semiconductor device according to the first embodiment.

FIG. 3 is a schematic sectional view illustrating a part of the semiconductor device according to the first embodiment.

FIG. 4 is a schematic sectional view illustrating a part of the semiconductor device according to the first embodiment.

FIG. 5 is an explanatory view of a method for manufacturing a semiconductor device according to the first embodiment.

FIG. 6 is an explanatory view of the method for manufacturing a semiconductor device according to the first embodiment.

FIG. 7 is an explanatory view of the method for manufacturing a semiconductor device according to the first embodiment.

FIG. 8 is an explanatory view of the method for manufacturing a semiconductor device according to the first embodiment.

FIG. 9 is an explanatory view of the method for manufacturing a semiconductor device according to the first embodiment.

FIG. 10 is an explanatory view of the method for manufacturing a semiconductor device according to the first embodiment.

FIG. 11 is an enlarged view of the schematic plan illustrating an example of a gate wire structure of the semiconductor device according to the first embodiment.

FIG. 12 is a schematic plan view illustrating an example of a termination trench of the semiconductor device according to the first embodiment.

FIG. 13 is an enlarged view of a schematic plan illustrating an example of a gate wire structure of the semiconductor device according to the first embodiment,

FIG. 14 is a schematic sectional view illustrating a part of a semiconductor device according to a second embodiment.

FIG. 15 is an explanatory view of a method for manufacturing a semiconductor device according to the second embodiment,

FIG. 16 is an explanatory view of the method for manufacturing a semiconductor device according to the second embodiment.

FIG. 17 is an explanatory view of the method for manufacturing a semiconductor device according to the second embodiment.

FIG. 18 is an explanatory view of the method for manufacturing a semiconductor device according to the second embodiment.

FIG. 19 is a schematic sectional view illustrating a part of a semiconductor device according to a third embodiment.

FIG. 20 is a schematic sectional view illustrating a part of a semiconductor device according to a fourth embodiment.

### DESCRIPTION OF EMBODIMENTS

Hereinafter, a semiconductor device and a method for manufacturing a semiconductor device according to embodiments of the present disclosure will be described in detail with reference to the drawings. For the sake of simplicity of description, details of semiconductor layers and electrodes may be omitted.

### First Embodiment

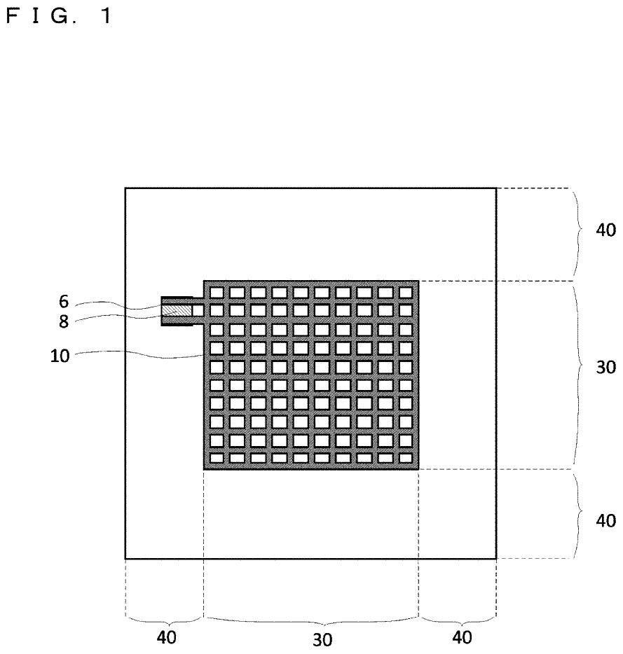

FIG. 1 is a plan view providing an overview of a semiconductor device according to the present embodiment of the present disclosure. As illustrated in FIG. 1, the semiconductor device includes an active region 30 and a termination region 40. The active region 30 includes a gate wire 10. The termination region 40 includes a termination trench 6, a termination insulating film 8, and a gate wire 10.

The active region 30 is a region that is provided in a central portion of the semiconductor device and causes a current to flow through the semiconductor device when a voltage is applied to the gate wire 10 formed in a grid pattern in the active region 30.

The termination region 40 is formed around the active region 30 and includes a guard ring intended to relax an electric field, for example, in addition to the termination trench 6, the termination insulating film 8, a gate insulating film 9, and the gate wire 10. The termination trench 6 is a trench provided in the termination region 40. The termination insulating film 8 is formed in the termination trench 6, and the gate insulating film 9 and the gate wire 10 are formed in a groove in a portion surrounded by an outer peripheral wall of the termination trench 6 and a side portion of the termination insulating film 8.

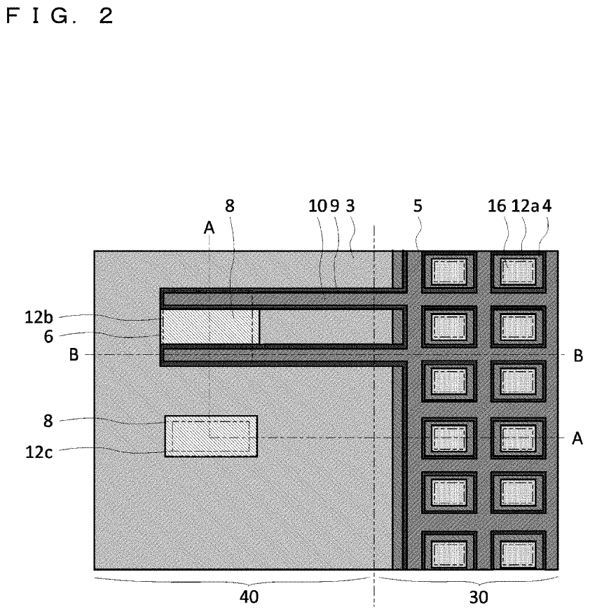

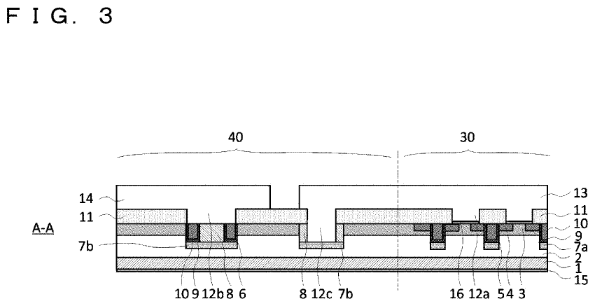

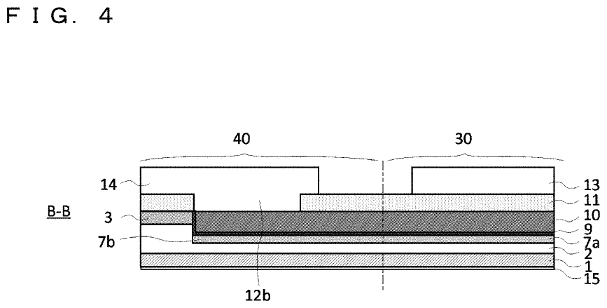

Next, a configuration in the vicinity of a boundary between the active region 30 and the termination region 40 of the semiconductor device according to the present embodiment will be described with reference to FIGS. 2, 3, and 4. FIG. 2 is an enlarged plan view providing an overview of the semiconductor device according to the present embodiment, and is an enlarged view of the vicinity of the termination trench 6 illustrated in FIG. 1. In FIG. 2, for the purpose of briefly describing the present embodiment, a source electrode 13, a gate electrode 14, a drain electrode 15, and an ohmic electrode 16 are omitted. FIGS. 3 and 4 are schematic sectional views illustrating a part of the semiconductor device according to the present embodiment. FIG. 3 illustrates a section taken along a line A-A in FIG. 2, and FIG. 4 illustrates a section taken along a line B-B in FIG. 2.

First, a configuration of the active region 30 will be described. As illustrated in FIG. 3, the active region 30 includes a semiconductor substrate 1, a drift layer 2, a base region 3, source regions 4, a gate trench 5, a diffusion protection layer 7a, the gate insulating film 9, the gate wire 10, an interlayer insulating film 11, the source electrode 13, the drain electrode 15, and the ohmic electrode 16.

The semiconductor substrate 1 is of a conductivity type of an N type, and is formed of silicon carbide that is doped with nitrogen as an N-type impurity and has a polytype of 4H.

The drift layer 2 is formed on the semiconductor substrate 1, is of an N type, and is formed of silicon carbide doped with nitrogen as an N-type impurity at an impurity concentration of 1×10¹⁴ cm⁻³ or higher and 1×10¹⁷ cm⁻³ or lower. The drift layer 2 has a thickness of 5 μm or larger and 200 μm or smaller.

The base region 3 is provided on a surface of the drift layer 2, is of a P type, and is formed of silicon carbide doped with aluminum as a P-type impurity at a concentration of 1×10¹⁷ cm³ or higher and 1×10²⁰ cm⁻³ or lower. The base region 3 has a depth of 1.0 μm or larger and 6.0 μm or smaller.

The source regions 4 are provided in a surface of the base region 3 while being spaced away from each other, are of an N type, and are formed of silicon carbide doped with nitrogen as an N-type impurity at a concentration of 1×10¹⁸ cm⁻³ or higher and 1×10²¹ cm⁻³ or lower. The source region 4 has a depth less than the depth of the base region 3.

The gate trench 5 is a trench that passes through the source region 4 and the base region 3 and reaches the drift layer 2, and is formed in a grid pattern in a plan view in the active region 30, for example. The gate trench 5 is formed so as to have a width and a depth each of 1 μm or larger and 10 μm or smaller. The diffusion protection layer 7a is formed in the drift layer 2 while being in contact with the bottom surface of the gate trench 5, is of a P type, and is formed of silicon carbide doped with aluminum as a P-type impurity at a concentration of 1×10¹⁷ cm⁻³ or higher and 1×10¹⁹ cm⁻³ or lower. The diffusion protection layer 7a is formed so as to have a thickness of 0.1 μm or larger and 2.0 μm or smaller.

The gate insulating film 9 is formed on the diffusion protection layer 7a and on the side portion of the gate trench 5, and is formed of a silicon oxide film having a thickness of 50 nm or larger and 80 nm or smaller, for example.

The gate wire 10 is formed on the gate insulating film 9 in the gate trench 5 and is formed of polysilicon. The gate wire 10 has a thickness and a width each of which is equal to a value obtained by subtraction of the thickness or the width of the gate insulating film 9 from the depth of the gate trench 5.

Here, as illustrated in FIG. 3, a first contact hole 12a is a hole that is formed in the interlayer insulating film 11 to electrically connect the source region 4 and the source electrode 13. The ohmic electrode 16 is a layer for reducing contact resistance, and is provided between the source region 4 and the source electrode 13. The ohmic electrode 16 is formed of a conductor such as a compound of metal and a semiconductor, silicide, or a plurality of metal layers, or a semiconductor. The source electrode 13 is formed on the interlayer insulating film 11, and the drain electrode 15 is formed on the back-surface side of the semiconductor substrate 1.

Next, a configuration of the termination region 40 will be described. As illustrated in FIG. 3, the termination region 40 includes the semiconductor substrate 1, the drift layer 2, the base region 3, a termination trench 6, a termination protection layer 7b, the termination insulating film 8, the gate insulating film 9, the gate wire 10, the interlayer insulating film 11, the source electrode 13, the gate electrode 14, and the drain electrode 15.

The termination trench 6 is a trench that is positioned closer to the outer surface of the semiconductor substrate 1 than the gate trench 5 in plan view, has a width larger than the width of the gate trench 5, and passes through the base region 3 to reach the drift layer 2 as illustrated in FIG. 3. The termination trench 6 is formed so as to have a depth larger than the depth of the base region 3, i.e., a depth of 1 μm or larger and 10 μm or smaller. In the termination trench 6, the termination insulating film 8, the gate insulating film 9, and the gate wire 10 are formed.

The termination protection layer 7b is formed in the drift layer 2 while being in contact with the bottom surface of the termination trench 6, is of a P type, and is formed of silicon carbide doped with aluminum as a P-type impurity at a concentration of 1×10¹⁷ cm⁻³ or higher and 1×10¹⁹ cm⁻³ or lower. In a case where the depth of the gate trench 5 is the same as the depth of the termination trench 6, the termination protection layer 7b is formed to have a thickness equal to the depth of the diffusion protection layer 7a, i.e., a thickness of 0.1 μm or larger and 2.0 μm or smaller.

The termination insulating film 8 is formed above the termination protection layer 7b in the termination trench 6 while being in contact with the termination protection layer 7b, and is formed of a silicon oxide film or a silicon nitride oxide film. The thickness of the termination insulating film 8 is equal to or larger than the thickness of the gate insulating film 9 and may be larger than the depth of the termination trench 6. As illustrated in FIG. 3, a groove reaching the termination protection layer 7b and having a section in a rectangular shape or a tapered shape is formed in a portion surrounded by the outer peripheral wall of the termination trench 6 and the side portion of the termination insulating film 8, and the groove has a width that is twice the width of the gate trench 5 or smaller. For example, in a case where the width of the gate trench 5 is 2.5 μm and the pitch between the adjacent gate trenches 5 is 5.0 μm, it suffices that the gate wire 10 buried in the gate trench 5 has a thickness of 2.5 μm or larger. In a case where the thickness of the gate wire 10 is 2.5 μm, the width of the groove in the portion surrounded by the outer peripheral wall of the termination trench 6 and the side portion of the termination insulating film 8 is twice the width of the gate trench 5 of 2.5 μm or smaller, that is, 5.0 μm or smaller. Here, by setting the width of the groove in the portion surrounded by the outer peripheral wall of the termination trench 6 and the side portion of the termination insulating film 8 to be equal to or smaller than twice the width of the gate trench 5, it is possible to suppress etching of the gate wire 10 in the groove in an etch-back process described later. This enables stable formation of the gate wire 10 in the groove, and so is more preferable.

As illustrated in FIG. 2, the gate wire 10 in the termination region 40 is formed in a stripe pattern in a plan view with the termination insulating film 8 in the termination trench 6 interposed therebetween. Further, the gate wire 10 in the active region 30 and the gate wire 10 in the termination region 40 are formed so as to be connected to each other between the gate trench 5 and the termination trench 6. As illustrated in FIG. 3, a second contact hole 12b is a hole formed in the interlayer insulating film 11 in order to electrically connect the gate wire 10 and the gate electrode 14 provided in contact with the gate wire 10 and the termination insulating film 8 in the termination trench 6. A third contact hole 12c is a hole that passes through the interlayer insulating film 11 and the base region 3 and reaches the drift layer 2 to electrically connect the termination protection layer 7b and the source electrode 13. The termination insulating film 8 is formed outside the third contact hole 12c, and the termination insulating film 8 insulates the source electrode 13 in the third contact hole 12c from the base region 3.

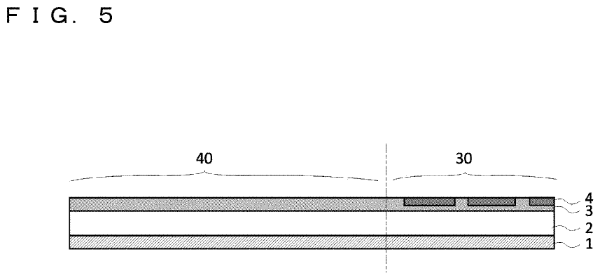

Next, a method for manufacturing a semiconductor device according to the present disclosure will be described sequentially with reference to FIGS. 5 to 10. FIGS. 5 to 10 are explanatory views of the method for manufacturing a semiconductor device according to the first embodiment. Here, description will be given with reference to the A-A section of FIG. 2. Hereinafter, aluminum can be used as a P-type impurity, and nitrogen can be used as an N-type impurity, but the impurities are not limited to any particular impurities, and other impurities known in general may be used.

FIG. 5 illustrates a state in which the drift layer 2, the base region 3, and the source regions 4 are formed on the semiconductor substrate 1.

For the semiconductor substrate 1, the semiconductor substrate 1 that is of a conductivity type of N type and is formed of silicon carbide having a polytype of 4H, is used.

An N-type epitaxial growth layer is formed on the surface of the semiconductor substrate 1 by a chemical vapor deposition (CVD) method. The epitaxial growth layer has an N-type impurity concentration of 1×10¹⁴ cm⁻³ or higher and 1×10¹⁷ cm⁻³ or lower, and a thickness of 5 μm or larger and 200 μm or smaller.

The base region 3 doped with a P-type impurity by ion implantation is formed on the surface of the epitaxial growth layer. The depth of the ion implantation of the P-type impurity is equal to or smaller than the thickness of the epitaxial growth layer, and is, for example, 0.3 μm or larger and 3 μm or smaller. The P-type impurity concentration of the base region 3 is equal to or higher than the N-type impurity concentration of the epitaxial growth layer, and is 1×10¹⁷ cm⁻³ or higher and 1×10²⁰ cm⁻³ or lower. A region where the epitaxial growth layer extends, except the base region 3, corresponds to the drift layer 2. Here, the base region 3 may be an epitaxially grown P-type semiconductor. In such a case, the P-type impurity concentration and the thickness of the base region 3 may be the same as the P-type impurity concentration and the thickness of the base region 3 formed by ion implantation.

An N-type impurity is selectively ion-implanted into the surface of the base region 3 to form the source regions 4. The source regions 4 are formed in a pattern corresponding to a layout of the gate electrode 14 formed in a later process. The depth of the ion implantation of the N-type impurity is smaller than the thickness of the base region 3. The N-type impurity concentration of the source region 4 is equal to or higher than the P-type impurity concentration of the base region 3, and is 1×10¹⁸ cm⁻³ or higher and 1×10²¹ cm⁻³ or lower.

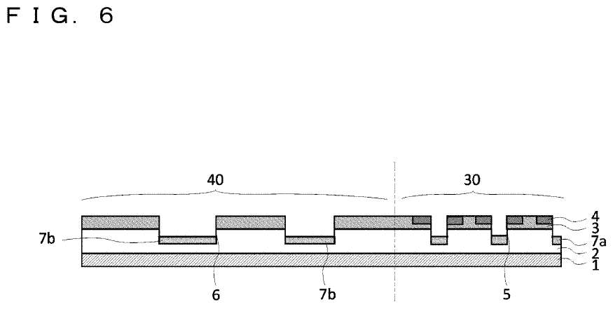

FIG. 6 illustrates a state in which the gate trench 5, the termination trench 6, the diffusion protection layer 7a below the gate trench 5, and the termination protection layer 7b below the termination trench 6 are formed.

After the above-described source regions 4 are formed, the base region 3 and the source regions 4 are selectively etched using photolithography and reactive ion etching to form the gate trench 5 and the termination trench 6. The depth of each of the gate trench 5 and the termination trench 6 is equal to or larger than the depth of the base region 3 and is 1.0 to 6.0 μm.

Subsequently, a P-type impurity is ion-implanted to form the diffusion protection layer 7a below the gate trench 5 and the termination protection layer 7b below the termination trench 6. The impurity concentration of each of the diffusion protection layer 7a and the termination protection layer 7b is 1×10¹⁷ cm³ or higher and 1×10¹⁹ cm⁻³ or lower, and the thicknesses of each of the diffusion protection layer 7a and the termination protection layer 7b is 0.1 μm or larger and 2.0 μm or smaller. In this regard, for each of the above-mentioned impurity concentrations, a desired value can be selected in consideration of the strength of an electric field that is generated in the gate insulating film 9 depending on the selected impurity concentration when the same voltage as the breakdown voltage of the semiconductor device is applied across the drain electrode 15 and the source electrode 13. Further, a P-type impurity is ion-implanted into the opening of the gate trench 5 from an oblique direction in forming the diffusion protection layer 7a, so that a P-type semiconductor layer is formed in the drift layer 2 in contact with the side surface of the gate trench 5. Thus, the P-type diffusion protection layer 7a and the P-type base region 3 can be connected via the P-type semiconductor layer.

Subsequently to the formation of the diffusion protection layer 7a and the termination protection layer 7b, an annealing process for activating the ion-implanted impurity is performed using a heat treatment apparatus. In the annealing process, heating is performed at 1300° C. to 1900° C. for 30 seconds to 1 hour in an inert gas atmosphere such as argon (Ar) or in vacuum.

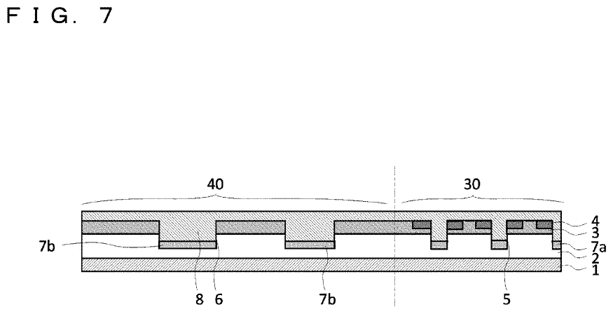

FIG. 7 illustrates a state in which the termination insulating film 8 is formed.

After the above-described annealing process, the termination insulating film 8 is formed in the active region 30 and the termination region 40. The termination insulating film 8 is formed of a silicon oxide film or a silicon nitride oxide film deposited by a CVD method and has a thickness equal to or larger than the depth of the termination trench 6. The reason why the thickness of the termination insulating film 8 is set to be equal to or larger than the depth of the termination trench 6 is to bury the gate wire 10 in the groove in the portion surrounded by the outer peripheral wall of the termination trench 6 and the side portion of the termination insulating film 8 simultaneously with the formation of the gate wire 10 in the gate trench 5.

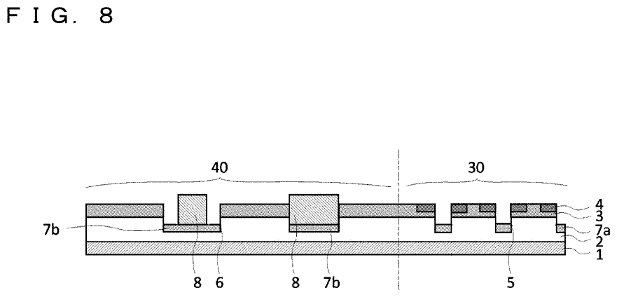

FIG. 8 illustrates a state in which the termination insulating film 8 is patterned and the groove in the portion surrounded by the outer peripheral wall of the termination trench 6 and the side portion of the termination insulating film 8 in the termination region 40 is formed.

The termination insulating film 8 is patterned by reactive ion etching using an etching mask or wet etching using hydrofluoric acid or the like. The patterning may be performed by using those etching techniques in combination. Then, the groove in the portion surrounded by the outer peripheral wall of the termination trench 6 and the side portion of the termination insulating film 8 is formed. In the patterning, a section with a rounded corner or the like, instead of a section in a perfectly rectangular shape or a perfectly tapered shape, may be formed. Alternatively, an un-etched portion of the termination insulating film 8 may be left thin on the bottom of the groove. In this manner, the termination insulating film 8 is formed in the termination trench 6 while being in contact with the termination protection layer 7b.

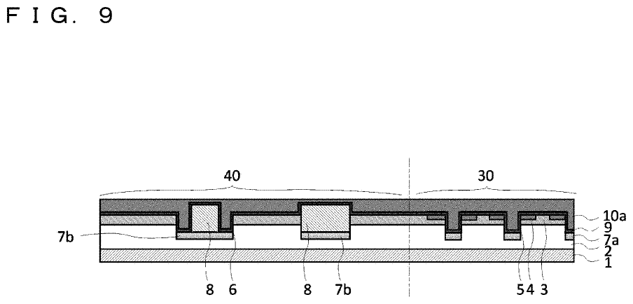

FIG. 9 illustrates a state in which the gate insulating film 9 and a gate wire layer 10a are deposited.

After the above-described etching mask is removed, the gate insulating film 9 is formed on the diffusion protection layer 7a in the active region 30 and the termination region 40 and on the side portions of the gate trench 5 and the termination trench 6. The gate insulating film 9 is formed of a silicon oxide film deposited by a CVD method, and has a thickness equal to or smaller than the thickness of the termination insulating film 8, and is 50 nm or larger and 80 nm or smaller.

After the gate insulating film 9 is formed, the gate wire layer 10a is deposited. The gate wire layer 10a is formed of polysilicon deposited by a low-pressure CVD method.

As a result, the gate insulating film 9 and the gate wire layer 10a are buried in the gate trench 5, the termination trench 6, and the groove in the portion surrounded by the outer peripheral wall of the termination trench 6 and the side portion of the termination insulating film 8. Here, the gate insulating film 9 may be formed by a thermal oxidation process or the like. The gate wire layer 10a can be deposited in the active region 30 and the termination region 40 at the same time, but can also be deposited separately, or can be formed of different materials.

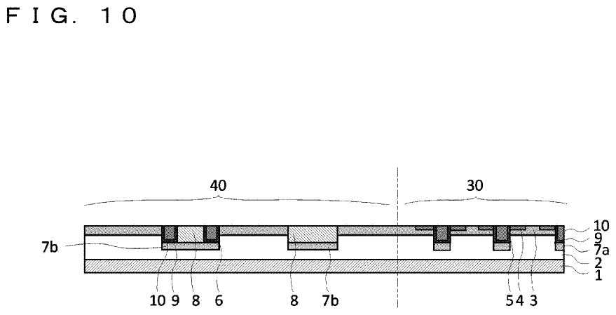

FIG. 10 illustrates a state in which the gate wire layer 10a and the like are etched back and the gate wire 10 is formed in the groove in the portion surrounded by the outer peripheral wall of the termination trench 6 and the side portion of the termination insulating film 8.

After the above-described gate wire layer 10a is deposited, the termination insulating film 8, the gate insulating film 9, and a portion of the gate wire layer 10a that extends off the termination trench 6 are etched by an etch-back process. Here, the gate wires 10 in the termination trench 6 in the section of FIG. 10 are placed in two positions with the termination insulating film 8 interposed therebetween without getting on the end of the opening of the termination trench 6.

Subsequently, the interlayer insulating film 11 is formed and patterned to form the first contact hole 12a, the second contact hole 12b, and the third contact hole 12c. The interlayer insulating film 11 is formed in the active region 30 and the termination region 40 by a low-pressure CVD method. The first contact hole 12a reaching the base region 3 and the source region 4 is formed in active region 30, and the second contact hole 12b reaching the gate wire 10 and the third contact hole 12c reaching the termination protection layer 7b are formed in the termination region 40.

Thereafter, the ohmic electrode 16 is formed in the first contact hole 12a formed in the active region 30. The ohmic electrode 16 is formed in such a manner that a metal film containing nickel (Ni) as a main component is formed on the base region 3 and the source region 4, and then Ni formed by heat treatment at 600° C. to 1100° C. is reacted with a semiconductor to form a silicide film, for example.

Further, an aluminum alloy or the like is deposited on the interlayer insulating film 11, in the first contact hole 12a, in the second contact hole 12b, and in the third contact hole 12c to form a metal electrode, and the metal electrode is patterned to be separated into the source electrode 13 and the gate electrode 14. Then, an aluminum alloy or the like is deposited on the back surface of the semiconductor substrate 1 to form the drain electrode 15. By the above-described processes, the semiconductor device according to the present embodiment is formed.

Next, functions and effects of the semiconductor device according to the present disclosure will be described.

In the semiconductor device of the present disclosure, a voltage applied across the source electrode 13 and the gate electrode 14 is controlled, so that a channel formed in the base region 3 facing the gate wire 10 with the gate insulating film 9 interposed therebetween is controlled. Then, an on state and an off state of the semiconductor device are controlled.

When a voltage for turning on the semiconductor device is applied across the source electrode 13 and the gate electrode 14, a voltage is applied from the gate electrode 14 to the gate wire 10. As a result, a channel is formed in the base region 3 facing the gate wire 10 with the gate insulating film 9 interposed therebetween, and a path through which electrons being carriers flow is formed between the N-type source region 4 and the N-type drift layer 2. Then, the electrons flowing from the source region 4 into the drift layer 2 reach the drain electrode 15, having passing through the drift layer 2 and the semiconductor substrate 1, because of an electric field formed by a voltage applied across the drain electrode 15 and the source electrode 13. As a result, applying a voltage equal to or higher than a threshold value to the gate wire 10 causes a current to flow from the drain electrode 15 to the source electrode 13.

Meanwhile, when a voltage for turning off the semiconductor device is applied across the source electrode 13 and the gate electrode 14, no channel is formed in the base region 3 facing the gate wire 10 with the gate insulating film 9 interposed therebetween. In this case, because of the presence of the P-type base region 3 between the N-type source region 4 and the N-type drift layer 2, no current flows from the drain electrode 15 to the source electrode 13.

When the semiconductor device is turned off, a high voltage supplied from an external electric circuit is applied across the drain electrode 15 and the source electrode 13, When the semiconductor device is in an off state, a depletion layer extends in the drift layer 2 owing to inclusion of the diffusion protection layer 7a and the termination protection layer 7b. Hence, an electric field caused by the voltage applied across the drain electrode 15 and the source electrode 13 is prevented from concentrating on the gate insulating film 9 on the bottom of the gate trench 5, whereby dielectric breakdown can be prevented despite application of a high electric field to the gate insulating film 9 on the bottoms of the gate trench 5 and the termination trench.

Meanwhile, when the semiconductor device is turned on, a current caused by a voltage supplied from the external electric circuit flows from the drain electrode 15 toward the source electrode 13, and hence the voltage across the drain electrode 15 and the source electrode 13 becomes equal to an on-voltage that is a voltage determined by a current flowing from the drain electrode 15 to the source electrode 13 and on-resistance of the semiconductor device. The on-voltage is much lower than the voltage applied across the drain electrode 15 and the source electrode 13 in an off state. Thus, the depletion layer extending from the diffusion protection layer 7a and the termination protection layer 7b into the drift layer 2 in an off state contracts toward the diffusion protection layer 7a and the termination protection layer 7b when the device is turned on. In a case where switching is performed in which the semiconductor device is placed into an on state and an off state alternately, the depletion layer extending from the diffusion protection layer 7a and the termination protection layer 7b into the drift layer 2 extends and contracts as the switching is performed, and a current flows through the diffusion protection layer 7a and the termination protection layer 7b via the source electrode 13. This current is a displacement current for charging and discharging equivalent capacitance of the depletion layer.

In the semiconductor device, during its operation in which an on state and an off state alternate, it is possible to relax voltage stress on the gate insulating film 9 by including the diffusion protection layer 7a and the termination protection layer 7b, whereby dielectric breakdown of the gate insulating film 9 can be prevented.

Further, according to the present disclosure, the termination insulating film 8 having a thickness equal to or larger than the thickness of the gate insulating film 9 is formed in the termination trench 6 wider than the gate trench 5, and the gate wires 10 are formed in two or more positions with the termination insulating film 8 interposed therebetween in a section of the termination trench 6. Thus, the gate wire 10 in the termination trench 6 is prevented from being thinned, or being lost as a film, due to the etching in the etch-back process. Then, the gate wire 10 can be electrically connected to the gate electrode 14 in a wide area without getting on the corner of the end of the opening of the termination trench 6. Therefore, when the semiconductor device is turned on, an electric field at the corner of the end of the opening of the termination trench 6 is reduced, thereby preventing deterioration of the gate insulating film 9 at the corner of the end of the trench opening in the termination region and reduction in reliability of the semiconductor device.

Additionally, the gate electrode 14 is provided on the gate wire 10 in termination region 40 while being in contact with the gate wire 10 in the present embodiment, but the ohmic electrode 16 may be formed between gate wire 10 and the gate electrode 14. The ohmic electrode 16 can be formed in such a manner that a metal film containing nickel (Ni) as a main component is formed on the base region 3 and the source region 4, and then Ni formed by heat treatment at 600° C. to 1100° C. is reacted with a semiconductor to form a silicide film, for example. Here, the ohmic electrode 16, as a part of the gate wire 10, contributes to electrical conduction between the gate wire 10 and the gate electrode 14. Hence, providing the ohmic electrode 16 is substantially synonymous with providing the gate electrode 14 on the gate wire 10 such that it is in contact with the gate wire 10.

Further, the example has been described in which the gate wire 10 in the termination trench 6 is in a pattern of stripes formed of parallel straight lines, but the gate wire 10 may have a shape of a polygonal line or an ellipse, for example, instead of being in a stripe pattern.

Further, the example has been described in which the thickness of the termination insulating film 8 is equal to or larger than the thickness of the gate insulating film 9, but the thickness of the termination insulating film 8 may be the same as the depth of the termination trench 6. This is because, in a case where the gate wire 10 is buried in the groove in the portion surrounded by the outer peripheral wall of the termination trench 6 and the side portion of the termination insulating film 8 as illustrated in FIG. 9, the groove is filled with the gate wire 10, and the gate wire 10 is prevented from being thinned or being lost though having been subjected to the etch-back process. Here, the thickness of the termination insulating film 8 corresponds to the length of the termination insulating film 8 formed between the bottom surface of the termination trench 6 and the bottom surface of the gate electrode 14 as illustrated in FIG. 3, for example. In this regard, the term “same” means not only being exactly the same, but also that a range of optimum design values in accordance with the depth of the termination trench 6 and the deposition amounts of the termination insulating film 8, the gate insulating film 9, and the gate wire layer 10a, a range of individual differences caused during manufacture, and a range of other tolerances and errors are included. For example, the combined thickness of an electric-field relaxation layer 17 and the termination insulating film 8 may be 80% or larger and 120% or smaller of the depth of the termination trench 6.

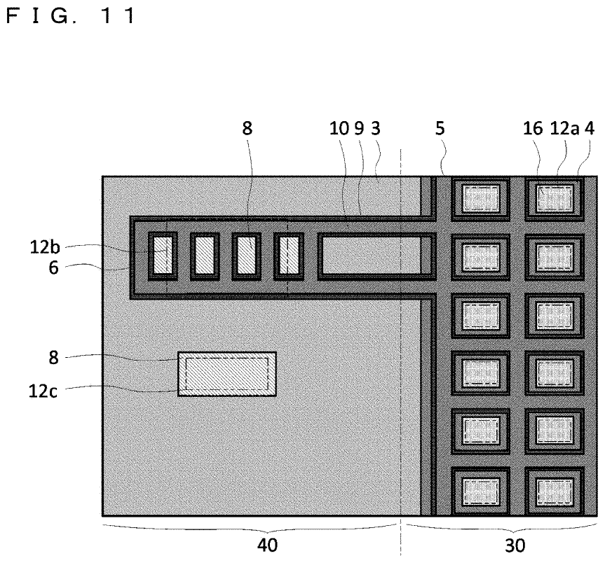

Further, the gate wire 10 may be formed in a grid pattern in which parallel straight lines are connected perpendicular to each other as illustrated in FIG. 11. A certain section may include three or more gate wires 10, and the termination insulating film 8 may be formed between each pair of the gate wires 10. Here, the gate electrode 14 is not formed on the outermost gate wire 10 in the termination trench 6, and the outermost gate wire 10 may be covered with the interlayer insulating film 11. A certain section of the termination trench 6 in FIG. 11 includes five gate wires 10, and the termination insulating film 8 is formed therebetween. The second contact hole 12b formed in the interlayer insulating film 11 is formed so as not to overlap the outermost gate wire 10 in a plan view, and is connected to the gate electrode 14 in three gate wires 10. Here, the gate insulating film 9 and the gate wire 10 are formed in a groove in a region sandwiched by the termination insulating films 8, and this groove is formed simultaneously with the groove in the portion surrounded by the outer peripheral wall of the termination trench 6 and the side portion of the termination insulating film 8. The grooves have similar widths in a plan view and have similar shapes in a sectional view.

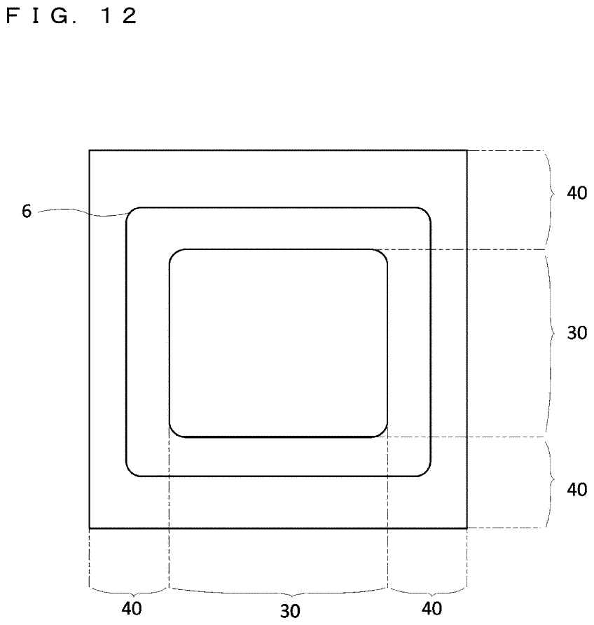

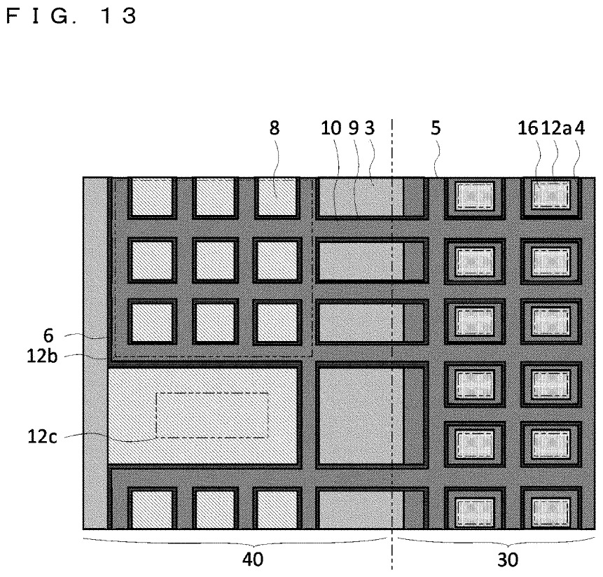

Further, the example has been described in which the termination trench 6 is provided in a part of the periphery of the active region 30, but the termination trench 6 may be formed in an endless ring shape continuously surrounding the active region 30 as illustrated in FIG. 12. Moreover, as illustrated in FIG. 13, the gate wire 10 in the termination region 40 may be formed in a pattern of larger grids. In a case where the gate wires 10 are connected in many positions between the active region 30 and the termination region 40 as described above, the gate wires 10 can be connected with low resistance between the active region 30 and the termination region 40. Further, to increase the opening area of the second contact hole 12b enables an increase of a connection area between the gate wire 10 and the gate electrode 14, whereby the gate wire 10 and the gate electrode 14 can be connected with low resistance. Here, it is only required that the width of the gate wire 10 in the termination region 40 is set such that the gate wire 10 is prevented from being thinned or being lost as a film by an etch-back process.

Furthermore, the example has been described in which the termination trench 6 is formed so as to have the same depth as the gate trench 5, but the termination trench 6 may be formed so as to have a different depth. In that case, from the viewpoint of the breakdown voltage of the gate insulating film 9 during the operation of the semiconductor device, the thickness of the termination protection layer 7b is desirable to be larger, and is preferably equal to or larger than the thickness of the diffusion protection layer 7a. Here, from the viewpoint of simplifying the steps of the manufacturing process, it is desirable that the diffusion protection layer 7a and the termination protection layer 7b have the same thickness, but the thicknesses of the diffusion protection layer 7a and the termination protection layer 7b may be appropriately selected as necessary.

Also with the above-described configuration, an electric field at the corner of the end of the opening of the termination trench 6 is reduced, thereby preventing deterioration of the gate insulating film 9 at the corner of the end of the trench opening in the termination region and reduction in reliability of the semiconductor device.

### Second Embodiment

In the first embodiment, the example has described in which the bottom of the groove in the portion surrounded by the outer peripheral wall of the termination trench 6 and the side portion of the termination insulating film 8 reaches the termination protection layer 7b. In the present embodiment, an example will be described in which the termination insulating film 8 is also present below the bottom of the groove in the portion surrounded by the outer peripheral wall of the termination trench 6 and the side portion of the termination insulating film 8 and the bottom of the groove does not reach the termination protection layer 7b. The configuration is similar to that of the first embodiment in the other respects, and description thereof will be omitted.

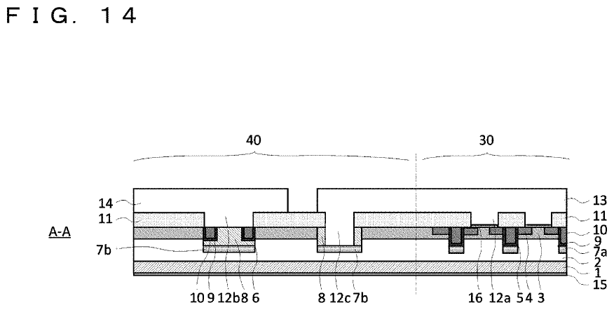

First, a configuration in the vicinity of a boundary between the active region 30 and the termination region 40 will be described with reference to FIG. 14. FIG. 14 is a schematic sectional view illustrating a part of the semiconductor device according to the present embodiment, and illustrates a section corresponding to the A-A section in FIG. 2.

As illustrated in FIG. 14, the termination insulating film 8 is also present below the bottom of the groove in the portion surrounded by the outer peripheral wall of the termination trench 6 and the side portion of the termination insulating film 8, and the bottom of the groove is closer to the surface side of the base region 3 than the bottom of the gate trench 5, in other words, is shallower than the gate trench 5. It suffices that the thickness of the termination insulating film 8 between the bottom of the groove in the portion surrounded by the outer peripheral wall of the termination trench 6 and the side portion of the termination insulating film 8 and the termination protection layer 7b is 20% or larger and 30% or smaller of the thickness of the termination insulating film 8 between the termination protection layer 7b and the gate electrode 14, for example. The gate insulating film 9 and the gate wire 10 are formed in the groove in the portion surrounded by the outer peripheral wall of the termination trench 6 and the side portion of the termination insulating film 8.

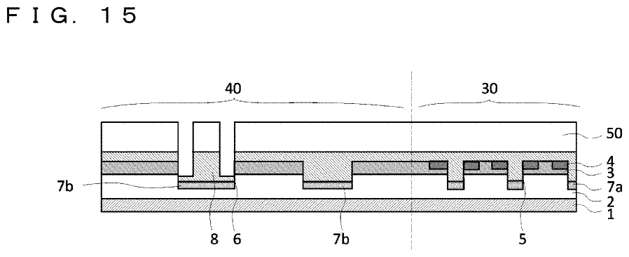

Next, regarding a method for manufacturing a semiconductor device according to the present embodiment, the steps up to the step in FIG. 7 that are similar to those in the first embodiment will be omitted, and the subsequent steps will be described with reference to FIGS. 15 to 18. FIGS. 15 to 18 are explanatory views of the method for manufacturing a semiconductor device according to the second embodiment. Below, description will be given with reference to a portion corresponding to the A-A section in FIG. 2.

FIG. 15 illustrates a state in which an etching mask 50 formed subsequently to the formation of the termination insulating film 8 is patterned and the groove in the portion surrounded by the outer peripheral wall of the termination trench 6 and the side portion of the termination insulating film 8 is formed.

After the section illustrated in FIG. 7 is formed, the termination insulating film 8 is etched in order to form the groove in the portion surrounded by the outer peripheral wall of the termination trench 6 and the side portion of the termination insulating film 8. In this embodiment, the etching ends before the bottom of the groove reaches the termination protection layer 7b. In other words, the etching ends midway before the termination insulating film 8 is penetrated. For the etching of the termination insulating film 8, reactive ion etching or wet etching using hydrofluoric acid or the like is used. Alternatively, a combination of those etching techniques may be used. Here, the etching mask 50 is formed on a portion except the termination trench 6 so that the portion is prevented from being etched.

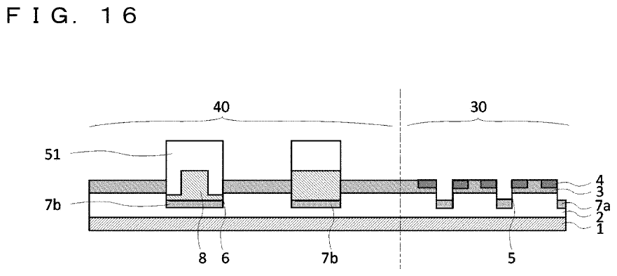

FIG. 16 illustrates a state in which an etching mask 51 formed after removal of the etching mask 50 is patterned and the termination insulating film 8 is etched.

After the section illustrated in FIG. 15 is formed, the etching mask 50 is removed, and subsequently, the etching mask 51 is formed and patterned, so that the termination insulating film 8 in the gate trench 5 or the like that is not covered with the etching mask 51 is etched. For the etching of the termination insulating film 8, reactive ion etching or wet etching using hydrofluoric acid or the like is used. Alternatively, a combination of those etching techniques may be used. Here, the etching mask 51 is formed so that the termination insulating film 8 in the termination trench 6 and in a groove of a connection portion between the termination protection layer 7b and the source electrode 13 is not etched.

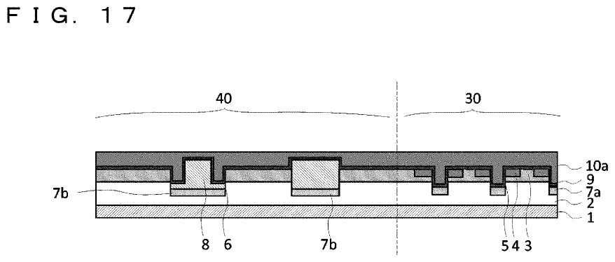

FIG. 17 illustrates a state in which the gate insulating film 9 and the gate wire layer 10a are deposited.

After the section illustrated in FIG. 16 is formed, the etching mask 51 is removed, and the gate insulating film 9 and the gate wire layer 10a are deposited in the active region 30 and the termination region 40.

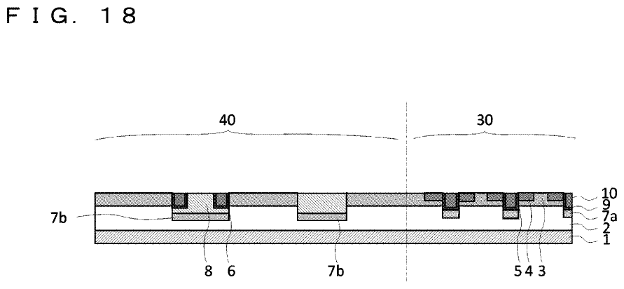

FIG. 18 illustrates a state in which the gate wire layer 10a is etched back and the gate wire 10 is formed in the groove in the portion surrounded by the outer peripheral wall of the termination trench 6 and the side portion of the termination insulating film 8.

After the section illustrated in FIG. 17 is formed, the termination insulating film 8, the gate insulating film 9, and a portion of the gate wire layer 10a that extends off the termination trench 6 are etched by an etch-back process. Here, the gate wires 10 in the termination trench 6 are placed in two positions with the termination insulating film 8 interposed therebetween without getting on the end of the opening of the termination trench 6.

The subsequent steps are similar to the steps after the formation of the interlayer insulating film 11 described in the first embodiment, and hence description thereof will be omitted.

As described above, in the present embodiment, in the same manner as in the first preferred embodiment, it is possible to prevent the gate wire 10 in the termination trench 6 from being thinned or being lost as a film due to the etching in the etch-back process. Then, the gate wire 10 can be electrically connected to the gate electrode 14 in a wide area without getting on the corner of the end of the opening of the termination trench 6. Therefore, when the semiconductor device is turned on, an electric field at the corner of the end of the opening of the termination trench 6 is reduced, thereby preventing deterioration of the gate insulating film 9 at the corner of the end of the trench opening in the termination region and reduction in reliability of the semiconductor device.

Furthermore, in the present embodiment, the termination protection layer 7b and the termination insulating film 8 are present between the gate insulating film 9 in the termination trench 6 and the drift layer 2 in a sectional view. Therefore, when the semiconductor device is turned off, an electric field generated in the gate insulating film 9 formed on the bottom of the groove in the portion surrounded by the outer peripheral wall of the termination trench 6 and the side portion of the termination insulating film 8 is relaxed, whereby dielectric breakdown of the gate insulating film 9 can be prevented.

### Third Embodiment

In the first embodiment, the example has described in which the bottom of the groove in the portion surrounded by the outer peripheral wall of the termination trench 6 and the side portion of the termination insulating film 8 reaches the termination protection layer 7b. In the present embodiment, an example will be described in which the bottom of the groove in the portion surrounded by the outer peripheral wall of the termination trench 6 and the side portion of the termination insulating film 8 is in contact with the electric-field relaxation layer 17 formed on the termination protection layer 7b. The configuration is similar to that of the first embodiment in the other respects, and description thereof will be omitted.

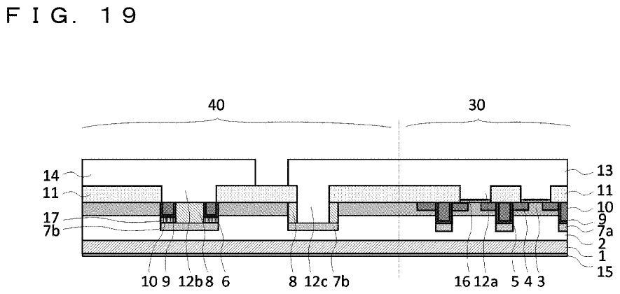

First, a configuration in the vicinity of a boundary between the active region 30 and the termination region 40 will be described with reference to FIG. 19. FIG. 19 is a schematic sectional view illustrating a part of the semiconductor device according to the present embodiment, and illustrates a section corresponding to the A-A section in FIG. 2.

As illustrated in FIG. 19, the bottom of the groove in the portion surrounded by the outer peripheral wall of the termination trench 6 and the side portion of the termination insulating film 8 is in contact with the electric-field relaxation layer 17 formed on the termination protection layer 7b. The electric-field relaxation layer 17 has an insulating property, has a relative dielectric constant higher than the relative dielectric constant of the termination insulating film 8, and has a thickness equal to or larger than the thickness of the gate insulating film 9 and smaller than the depth of the termination trench 6. The electric-field relaxation layer 17 is formed of a nitride oxide film. However, the material is not limited to a nitride oxide film, and any material that has a relative dielectric constant higher than the relative dielectric constant of the termination insulating film 8, such as an insulator containing tantalum or yttrium, can be used. In this embodiment, a thickness of the termination insulating film 8 corresponding to the length from the upper surface of the termination protection layer 7b to the bottom surface of the gate electrode 14 may be the same as the depth of the termination trench 6. This is because, in a case where the gate wire 10 is buried in the groove in the portion surrounded by the outer peripheral wall of the termination trench 6 and the side portion of the termination insulating film 8, the groove is filled with the gate wire 10, and the gate wire 10 is prevented from being thinned or being lost though having been subjected to the etch-back process. In this regard, the term “same” means not only being exactly the same, but also that a range of optimum design values in accordance with the depth of the termination trench 6 and the deposition amounts of the termination insulating film 8, the gate insulating film 9, and the gate wire layer 10a, a range of individual differences caused during manufacture, and a range of other tolerances and errors are included. For example, the combined thickness of the electric-field relaxation layer 17 and the termination insulating film 8 may be 80% or larger and 120% or smaller of the depth of the termination trench 6.

Next, a method for manufacturing a semiconductor device according to the present embodiment will be described. Before the termination insulating film 8 in FIG. 7 described in the first embodiment is formed, the electric-field relaxation layer 17 is formed so as to extend from the active region 30 to the termination region 40 in the same manner as the termination insulating film 8, The electric-field relaxation layer 17 is formed by a CVD method in the same manner as the termination insulating film 8, but may be formed by another generally-known method of forming an insulating film.

Subsequently, the termination insulating film 8 is formed and is subjected to a patterning process. Etching is performed to such a degree that the termination insulating film 8 is penetrated, in other words, a groove being formed reaches the electric-field relaxation layer 17. As a result, the bottom of the groove in the portion surrounded by the outer peripheral wall of the termination trench 6 and the side portion of the termination insulating film 8 is in contact with the electric-field relaxation layer 17. The subsequent steps after the formation of the termination insulating film 8 are similar to the steps described in the first embodiment, and hence description thereof will be omitted.

Note that, in FIG. 19, the electric-field relaxation layer 17 is formed only below the groove in the portion surrounded by the outer peripheral wall of the termination trench 6 and the side portion of the termination insulating film 8, but the electric-field relaxation layer 17 may be formed so as to cover the upper surface of the termination protection layer 7b in the termination trench 6 because the electric-field relaxation layer 17, like the termination insulating film 8, is an insulating film, and functions as a part of the termination insulating film 8. In this case, the total thickness of the thickness of the electric-field relaxation layer 17 and the thickness of the termination insulating film 8 may be the same as the depth of the termination trench 6. This is because, in a case where the gate wire 10 is buried in the groove in the portion surrounded by the outer peripheral wall of the termination trench 6 and the side portion of the termination insulating film 8, the groove is filled with the gate wire 10, and the gate wire 10 is prevented from being thinned or being lost though having been subjected to the etch-back process. In this regard, the term “same” means not only being exactly the same, but also that a range of optimum design values in accordance with the depth of the termination trench 6 and the deposition amounts of the termination insulating film 8 and the gate wire 10, a range of individual differences caused during manufacture, and a range of other tolerances and errors are included. For example, the combined thickness of the electric-field relaxation layer 17 and the termination insulating film 8 may be 80% or larger and 120% or smaller of the depth of the termination trench 6.

As described above, in the present embodiment, in the same manner as in the first preferred embodiment, it is possible to prevent the gate wire 10 in the termination trench 6 from being thinned or being lost as a film due to the etching in the etch-back process. Then, the gate wire 10 can be electrically connected to the gate electrode 14 in a wide area without getting on the corner of the end of the opening of the termination trench 6. Therefore, when the semiconductor device is turned on, an electric field at the corner of the end of the opening of the termination trench 6 is reduced, thereby preventing deterioration of the gate insulating film 9 at the corner of the end of the trench opening in the termination region and reduction in reliability of the semiconductor device.

Furthermore, in the present embodiment, the termination protection layer 7b and the electric-field relaxation layer 17 having a relative dielectric constant higher than the relative dielectric constant of the termination insulating film 8 are present between the gate insulating film 9 in the termination trench 6 and the drift layer 2 in a sectional view, Therefore, when the semiconductor device is turned off, an electric field generated in the gate insulating film 9 formed on the bottom of the groove in the portion surrounded by the outer peripheral wall of the termination trench 6 and the side portion of the termination insulating film 8 is relaxed in accordance with the capacitance corresponding to the relative dielectric constant of the electric-field relaxation layer 17, whereby dielectric breakdown of the gate insulating film 9 can be prevented.

Note that, in the etching after the formation of the termination insulating film 8, the termination insulating film 8 may be un-penetrated, the termination insulating film 8 and the electric-field relaxation layer 17 may be present below the bottom of the groove in the portion surrounded by the outer peripheral wall of the termination trench 6 and the side portion of the termination insulating film 8, and the bottom of the groove may be in contact with the termination insulating film 8. In this case, when the semiconductor device is turned off, an electric field generated in the gate insulating film 9 formed on the bottom of the groove in the portion surrounded by the outer peripheral wall of the termination trench 6 and the side portion of the termination insulating film 8 is relaxed by the electric-field relaxation layer 17 and the termination insulating film 8, whereby dielectric breakdown of the gate insulating film 9 can be prevented. Further, FIG. 19 illustrates the example in which the termination insulating film 8 is formed on the electric-field relaxation layer 17 while being in contact with the electric-field relaxation layer 17. However, the electric-field relaxation layer 17 is not necessarily required to be formed in that contact region, and the termination insulating film 8 may be formed on the termination protection layer 7b. Also in this case, when the semiconductor device is turned off, an electric field generated in the gate insulating film 9 formed on the bottom of the groove in the portion surrounded by the outer peripheral wall of the termination trench 6 and the side portion of the termination insulating film 8 is relaxed by the electric-field relaxation layer 17 and the termination insulating film 8, whereby dielectric breakdown of the gate insulating film 9 can be prevented.

### Fourth Embodiment

In the first embodiment, the example has been described in which the gate wire 10 on the termination insulating film 8 in the termination trench 6 is etched by an etch-back process, but in the present embodiment, an example will be described in which the gate wire 10 is formed on the termination insulating film 8 in the termination trench 6. The configuration is similar to that of the first embodiment in the other respects, and description thereof will be omitted.

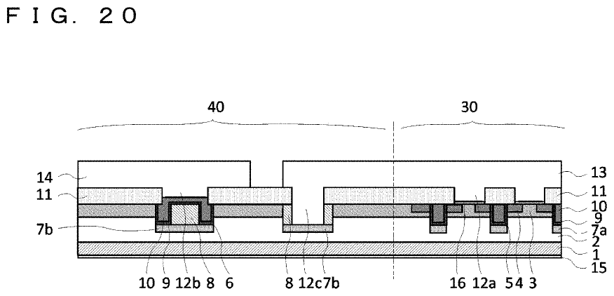

First, a configuration in the vicinity of a boundary between the active region 30 and the termination region 40 will be described with reference to FIG. 20. FIG. 20 is a schematic sectional view illustrating a part of the semiconductor device according to the present embodiment, and illustrates a section corresponding to the A-A section in FIG. 2.

As illustrated in FIG. 20, the gate insulating film 9 and the gate wire 10 are formed on the termination insulating film 8 in the termination trench 6. The gate wire 10 on the termination insulating film 8 has a thickness of 0.1 μm or larger. Here, the gate wire 10 and the gate electrode 14 are connected via a bonding surface having an area similar to the opening area of the termination trench 6.

Next, a method for manufacturing a semiconductor device according to the present embodiment will be described. After the gate wire 10 in FIG. 9 described in the first embodiment is formed, an etching mask is formed on the gate wire 10 over the active region 30 and the termination region 40, and the etching mask other than a portion thereof above the termination trench 6 is removed while the portion is left unremoved. Then, the termination insulating film 8, the gate insulating film 9, and a portion of the gate wire 10 that extends off the termination trench 6 are etched by an etch-back process, and thereafter the etching mask is removed. As a result, the gate insulating film 9 and the gate wire 10 are formed on the termination insulating film 8 in the termination trench 6 without the gate wire 10 in the termination trench 6 getting on the end of the opening of the termination trench 6.

Here, the region in the gate wire 10 covered with the etching mask can be determined such that the gate wire 10 in the termination trench 6 is prevented from getting on the end of the opening of the termination trench 6, and for example, it suffices that the region is almost as large as the opening area of the second contact hole 12b illustrated in FIG. 20. The steps subsequent to the formation of the interlayer insulating film 11 are similar to the steps described in the first embodiment, and hence description thereof will be omitted.

As described above, in the present embodiment, in the same manner as in the first preferred embodiment, it is possible to prevent the gate wire 10 in the termination trench 6 from being thinned or being lost as a film due to the etching in the etch-back process. Then, the gate wire 10 can be electrically connected to the gate electrode 14 in a wide area without getting on the corner of the end of the opening of the termination trench 6. Therefore, when the semiconductor device is turned on, an electric field at the corner of the end of the opening of the termination trench 6 is reduced, thereby preventing deterioration of the gate insulating film 9 at the corner of the end of the trench opening in the termination region and reduction in reliability of the semiconductor device.

Furthermore, in the present embodiment, the gate insulating film 9 and the gate wire 10 are formed on the termination insulating film 8 in the termination trench 6, and the gate wire 10 and the gate electrode 14 are connected via a bonding surface having almost the same area as the opening area of the termination trench 6. Therefore, the gate wire 10 and the gate electrode 14 can be electrically connected in a larger area than that in the first preferred embodiment, and thus can be connected with lower resistance.

Note that, in the present disclosure, the materials, the method of forming each layer and each region, and the numerical values of the concentration, the thickness, and the depth are not limited to those described as examples, and can be appropriately changed.

Further, regarding the semiconductor device, the example has been described in which the first conductivity type is an N-type and the second conductivity type is a P-type, but a semiconductor device in which the first conductivity type is a P-type and the second conductivity type is an N-type may be used.

Further, the example has been described in which the semiconductor device is a MOSFET, but the semiconductor device may be an IGBT, and in such a case, the conductivity type of the semiconductor substrate 1 is a P-type.

Further, the example has been described in which the drift layer 2 is silicon carbide, but the drift layer 2 may be a wide band-gap semiconductor such as gallium nitride or diamond.

Further, in the present disclosure, the drawings are schematically illustrated, and mutual relationships in size and position between images illustrated in different drawings are not necessarily accurately described, and can be appropriately changed. Further, the terms meaning specific positions and directions such as “upper”, “lower”, “side”, “bottom”, “front”, and “back” are used in some portions, and these terms are used for the purpose of facilitating understanding of the contents of the embodiments and are not intended to make them equal to directions in practical applications.

### EXPLANATION OF REFERENCE SIGNS

1: semiconductor substrate
2: drift layer
3: base region
4: source region
5: gate trench
6: termination trench
7a: diffusion protection layer
7b: termination protection layer
8: termination insulating film
9: gate insulating film
10: gate wire
10a: gate wire layer
11: interlayer insulating film
12a: first contact hole
12b: second contact hole
12c: third contact hole
13: source electrode
14: gate electrode
15: drain electrode
16: ohmic electrode
17: electric-field relaxation layer
30: active region
40: termination region
50, 51: etching mask

1. A semiconductor device comprising:
a semiconductor substrate;
a drift layer of a first conductivity type provided on the semiconductor substrate;
a base region of a second conductivity type provided on the drift layer;
a plurality of source regions of the first conductivity type provided on the base region while being spaced away from each other;
a gate trench passing through the source region and the base region and reaching the drift layer;
a termination trench positioned in a termination region on an outer peripheral side of an active region where the gate trench is formed, the termination trench having a width larger than a width of the gate trench and passing through the base region to reach the drift layer;
a diffusion protection layer of the second conductivity type formed in the drift layer while being in contact with a bottom surface of the gate trench;
a termination protection layer of the second conductivity type formed in the drift layer while being in contact with a bottom surface of the termination trench;
a gate insulating film formed on the diffusion protection layer, the termination protection layer, a side portion of the gate trench, and a side portion of the termination trench;
a termination insulating film formed above the termination protection layer in the termination trench while being in contact with the termination protection layer, the termination insulating film having a thickness equal to or larger than a thickness of the gate insulating film;
gate wires formed on the gate insulating film on an inner side of the gate trench in the gate trench, and formed in grooves in two or more portions with the termination insulating film interposed therebetween in one section, surrounded by an outer peripheral wall of the termination trench and a side portion of the termination insulating film in the termination trench, the gate wires being connected between the gate trench and the termination trench;
a source electrode electrically connected to the source region and the termination protection layer; and
a gate electrode provided on the gate wire in the termination trench and on the termination insulating film while being in contact with the gate wire and the termination insulating film, the gate electrode being electrically connected to the gate wire,
wherein the gate wire in the termination trench is formed in a grid pattern in a plan view.

2. The semiconductor device according to claim 1, wherein a width of the groove is twice a width of the gate trench, or smaller.

3. (canceled)

4. The semiconductor device according to claim 1, wherein a thickness of the termination insulating film corresponding to a length from a bottom surface of the termination trench to a bottom surface of the gate electrode is the same as a depth of the termination trench.

5. The semiconductor device according to claim 1, wherein the termination insulating film is further formed between a bottom of the groove and the termination protection layer.

6. The semiconductor device according to claim 1, wherein a bottom of the groove is in contact with an electric-field relaxation layer that has a relative dielectric constant higher than a relative dielectric constant of the termination insulating film and is provided on the termination protection layer.

7. The semiconductor device according to claim 1, wherein
the gate wire is further provided on the termination insulating film,
the gate wires formed in the grooves are connected to each other by the gate wire on the termination insulating film, and
the gate wire on the termination insulating film and the gate electrode are electrically connected.

8. A method for manufacturing a semiconductor device comprising:
a step of forming a drift layer of a first conductivity type on a surface of a semiconductor substrate;
a step of forming a base region of a second conductivity type on the drift layer;
a step of forming a plurality of source regions of the first conductivity type spaced away from each other on the base region;
a step of forming a gate trench passing through the source region and the base region and reaching the drift layer;
a step of forming a termination trench having a width larger than a width of the gate trench and passing through the base region to reach the drift layer, in a termination region on an outer peripheral side of an active region where the gate trench is formed;
a step of forming a diffusion protection layer of the second conductivity type in the drift layer such that the diffusion protection layer is in contact with a bottom surface of the gate trench;
a step of forming a termination protection layer of the second conductivity type in the drift layer such that the termination protection layer is in contact with a bottom surface of the termination trench;
a step of forming a termination insulating film above the termination protection layer in the termination trench such that the termination insulating film is in contact with the termination protection layer;
a step of forming a gate insulating film having a thickness equal to or smaller than a thickness of the termination insulating film on the diffusion protection layer, the termination protection layer, a side portion of the gate trench, and a side portion of the termination trench;
a step of etching back a gate wire layer after deposition of the gate wire layer on the termination insulating film and the gate insulating film, to form gate wires on the gate insulating film on an inner side of the gate trench in the gate trench, and in grooves in two or more portions with the termination insulating film interposed therebetween in one section, surrounded by an outer peripheral wall of the termination trench and a side portion of the termination insulating film in the termination trench such that the gate wires are connected between the gate trench and the termination trench;
a step of forming a source electrode electrically connected to the source region and the termination protection layer; and
a step of forming a gate electrode on the gate wire in the termination trench and on the termination insulating film such that the gate electrode is in contact with the gate wire and the termination insulating film and the gate electrode is electrically connected to the gate wire.
